(19) United States
(12) Patent Application Publication
(10) Pub. No.: US 2010/0101640 A1
(43) Pub. Date: Apr. 29, 2010

(54) Optical structure and solar cell using the same

(76) Inventors: Jain-Cheng Chen, Kaohsiung County (TW); Chung-Ying Wu, Tainan County (TW); Hsiung-Yu Tsai, Zhubei City (TW); Wen-Chun Yeh, Taoyuan County (TW); Chen-Hsiang Hsu, Taoyuan County (TW); Tim Hsiao, Taoyuan County (TW); Shih-Chi Chien, Taipei City (TW)

Correspondence Address: Raymond Sun, 12420 Woodhall Way, Tustin, CA, 92782, US

(21) Appl. No.: 12/384,510

(22) Filed: Apr. 6, 2009

(30) Foreign Application Priority Data
Apr. 9, 2008 (TW) 097206049

(51) Int. Cl. H01L 31/0236; H01L 31/0232; H01L 31/04; G02B 27/12

(52) U.S. Cl. 136/256; 250/214 R; 250/216; 359/619

(57) ABSTRACT

An optical structure is characterized by improving a primary lens of a photovoltaic concentrator system. The optical structure is accomplished by properly dividing the primary lens, determining required optical operational regions, and arranging the optical operational regions basing on an identical location into an annular array, thereby forming the complete optical structure. The optical structure facilitates enhancing uniformity of light distribution throughout the optical operational regions, improving photoelectric conversion efficiency of a solar cell having the optical structure, and reducing operational distance between the primary lens and the solar cell.

### BACKGROUND OF INVENTION

1. Field of the Invention The present invention relates to an optical structure applicable to a concentrator system in a solar cell.

2. Description of the Prior Art

In recent years, due to increasing energy costs and global warming issues, requests for renewable energy bringing less contamination have attracted extensive attention. Especially, solar photovoltaic systems relying on the unfailing solar energy have been developed with various materials and techniques in a worldwide scale for pursuing maximized photoelectric conversion efficiency and reduced power generation costs. Typically, a photovoltaic concentrator system comprises a condensing lens and a high-efficiency solar cell, thereby providing excellent power-generation efficiency with reduced costs of land use per unit area. Besides, such solar photovoltaic systems are not only superior to the traditional thermal power generation solutions in economy but also free from concerns related to waste gas and noise, thus having potential of market growth.

Conventionally, a Fresnel lens is implemented to substantially focus sunlight on the center of a solar cell. Though the Fresnel lens facilitates photocurrent generation, it nevertheless causes uneven current distribution that results in significant loss of heat from resistors and high operating temperature thereof, thus bringing about deteriorating efficiency of the solar cell. In addition to improving thermal dissipation, another approach to enhancing the photoelectric conversion efficiency in a solar cell is to use a Fresnel lens to provide better uniformity of light concentration.

Please refer to FIG. 1 for a primary lens 2 of a typical photovoltaic concentrator system. Therein, a Fresnel lens or a mirror is provided to gather sunlight rays 1 into a concentration region 3. Optical properties of light vary with wavelengths of light. Hence, variation in the extent of concentration increases markedly when light of a wide range of wavelengths enters the primary lens 2.

For instance, there is a great difference in the refractive index of the same plastic material between a light ray with a long wavelength and a light ray with a short wavelength. Under non-total reflection, if light rays with different wavelengths fall on the same optical material at the same incidence angle, the light rays leave the optical material at different emergence angles, depending on wavelength. This can be easily proven by putting an observation plane behind the optical material.

When applied to collection of light with multiple wavelengths, a solar cell using the traditional primary lens becomes inefficient, because the photoelectric conversion efficiency of the solar cell is highly associated with the range of concentration of light energy involving specific wavelengths of light. Particularly, assuming that different light wavelengths are associated with different concentration ranges, to collect light energy to the full from light rays of all effective wavelengths, a solar cell must has its concentration region made large enough to meet the light wavelength that requires the largest concentration range. However, most of collectable light rays are only available to part of the solar cell, causing inefficient utilization of the solar cell.

Please refer to FIG. 2A for a top view of a conventional primary lens 2 that has been designed and cut into a square. FIG. 2B is a partially enlarged view of the primary lens 2 shown in FIG. 2A. FIG. 2C is a polar diagram derived in a conventional illumination test where a light source with a short wavelength at 546.1 nm passes through the conventional primary lens 2. FIG. 2D is a polar diagram showing a light source with a long wavelength at 1300 nm passing through the conventional primary lens 2. Through FIGS. 2C and 2D, it is learned that light rays with different wavelengths cause different concentration ranges.

### SUMMARY OF INVENTION

An objective of the present invention is to provide an optical structure that comprises a plurality of optical operational regions linked up in an annular array and based at the same location so as to increase focal points.

Another objective of the present invention is to provide an optical structure that implements a plurality of focal points to distribute light over a photoelectric conversion module so as to maintain a solar cell using the optical structure at a relatively low operating temperature and improve photoelectric conversion efficiency of the solar cell.

The previously mentioned conventional photovoltaic concentrator system needs a conventional primary lens for collecting sunlight. However, the conventional primary lens fails to accurately concentrate light rays of different wavelengths in the same area but presents a variable concentration region in answering to the light rays with different wavelengths. Hence, the present invention is aimed at improving the conventional primary lens for a solar photovoltaic system so as to enable the improved optical structure to concentrate light rays with different wavelengths in a certain operational region. Besides, the present invention equalizes concentration areas of light rays with different wavelengths so as to allow full use of the light rays, thereby enhancing light uniformity and luminance, and significantly improving efficiency of the solar cell. The optical structure of the present invention can be easily applied to the conventional primary lens and thus is economically beneficial.

According to a known principle of optics, the smaller the included angle between the direction in which light rays with different wavelengths travel and the normal vector of a solar cell, the closer the locations where the light rays enter the solar cell. Given the aforementioned principle, the present invention appropriately divides an existing primary lens as needed, so as to limit boundaries of concentration areas of light rays with different wavelengths to a certain range. Thus, when ranges required by plural identical primary optical operational regions are all limited, light rays with different wavelengths can be collected in a limited range. From another respect, the present invention features limiting light rays in a certain area where the light rays overlap, thereby improving photoelectric conversion efficiency of the solar cell reasonably.

In view of this, the present invention involves appropriately dividing a primary lens and determining required optical operational regions. Therein, a plurality of said optical operational regions are linked up in an annular array based at the same location so as to construct a complete optical structure. By the improved optical structure, the present invention facilitates improving uniformity throughout the operational regions and increasing the number of focal points, thereby lowering operating temperature, improving photoelectric conversion efficiency, maximizing the service life of the solar cell, and reducing the operational distance between the primary lens and the solar cell.

### BRIEF DESCRIPTION OF THE DRAWINGS

The invention as well as a preferred mode of use, further objectives and advantages thereof will be best understood by reference to the following detailed description of an illustrative embodiment when read in conjunction with the accompanying drawings, wherein:

FIG. 1 is a schematic drawing showing light paths of a conventional primary lens;

FIG. 2A is a top view the conventional primary lens;

FIG. 2B is a partially enlarged view of the conventional primary lenses;

FIG. 2C is a polar diagram showing a light source with a wavelength at 546.1 nm passing through the conventional primary lens and presented in a concentration region;

FIG. 2D is a polar diagram showing a light source with a wavelength at 1300 nm passing through the conventional primary lens and presented in a concentration region;

FIG. 3A is a schematic drawing showing divisional lines on a primary lens according to the present invention;

FIG. 3B is a schematic drawing showing four optical operational regions after division jointly forming a complete optical structure of the present invention;

FIG. 3C is a partially enlarged vie of the optical structure of the present invention;

FIG. 3D is a polar diagram showing a light source with a wavelength at 546.1 nm passing through the optical structure of the present invention and presented in a concentration region;

FIG. 3E is a polar diagram showing a light source with a wavelength at 1300 nm passing through the optical structure of the present invention and presented in a concentration region;

FIG. 4 is a sectional view of the optical structure of the present invention;

FIG. 5 is a schematic drawing describing a solar cell using the optical structure of the present invention; and

FIGS. 6A and 6B are maps of energy distribution measured and plotted against different distances between the disclosed optical structure and a semiconductor chip in the solar cell.

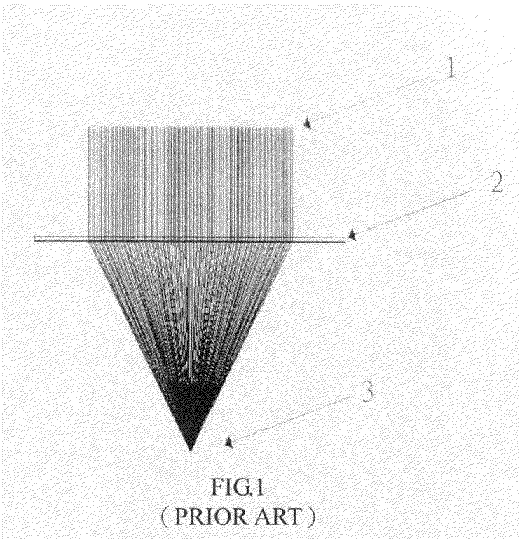

### DETAILED DESCRIPTION OF THE PREFERRED EMBODIMENT

The present invention is characterized by dividing a typical primary lens 2 into several optical operational regions. To define each said optical operational region, divisional benchmarks are determined taking similar light-entering ranges of light wavelengths. Besides, a divisional angle is determined according to a shape of a concentration region, wherein the angle is derived from dividing 360 degrees by N, where N denotes the number of sides of the polygonal concentration region. Furthermore, the area of the intended concentration region is controlled by a distance between the concentration region and the benchmarks. Afterward, a tip of the optical operational region is taken as a center of rotation so as to form an annular array filling the 360-degree area. Hence, N-1 said regions are integrated into a whole optical structure, thereby accomplishing the present invention.

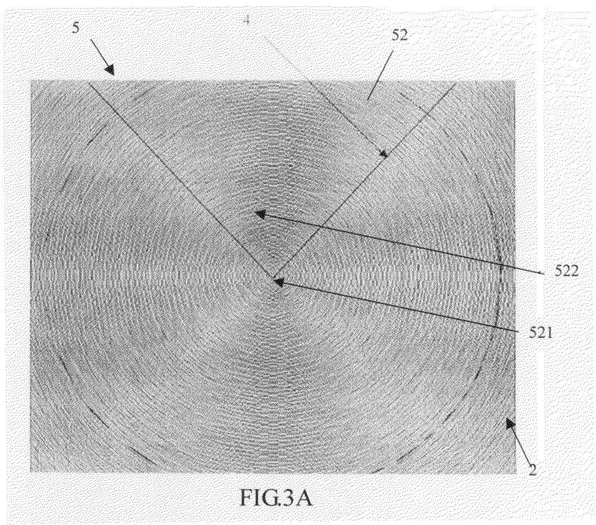

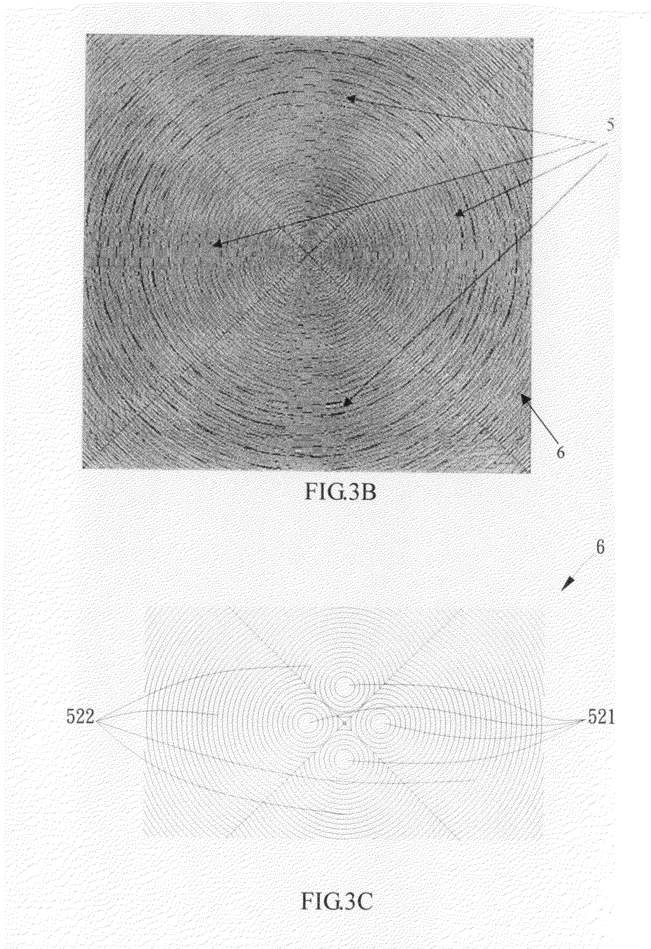

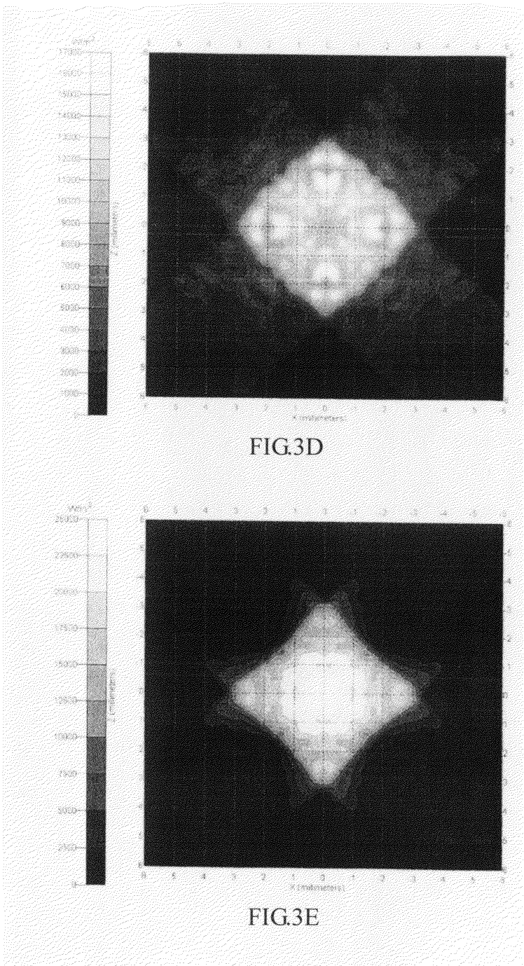

Please refer to FIG. 3A. Therein, a triangular optical operational region 5 is defined on a typical rectangular primary lens 2 along divisional lines 4 adjacent to benchmarks. The optical operational region 5 includes a rough side 52. At the rough side 52, a central circle 521 is located at a tip of the optical operational region 5, and a plurality of refraction portions 522 of concentric arc-shape are arranged on the circumference of the central circle 521.

Referring to FIGS. 3B and 3C, according to the present embodiment, four identical said optical operational regions 5 are arranged in an annular array such that the optical operational regions 5 encircle a center comprising the central circles 521 on the tips thereof, thereby forming an optical structure 6 shaped as a complete square. Boundaries between adjacent said optical operational regions 5 may be realized by any proper connection approach. Of course, the number of the optical operational regions 5 is not to be limited by the present embodiment. Instead, the primary lens 2 may be divided into any number of the optical operational regions 5 as needed.

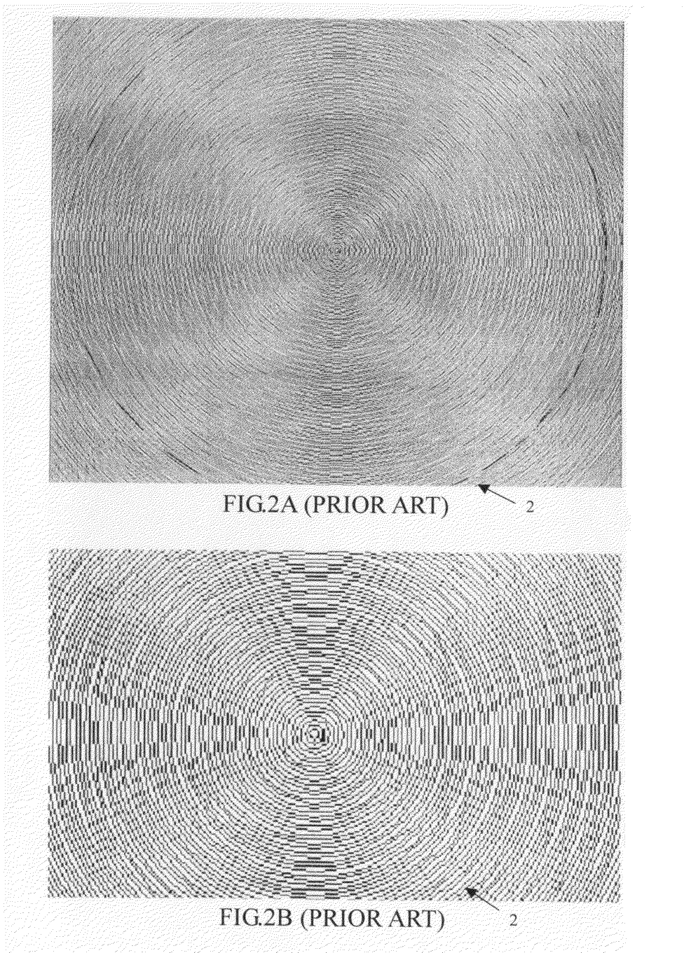

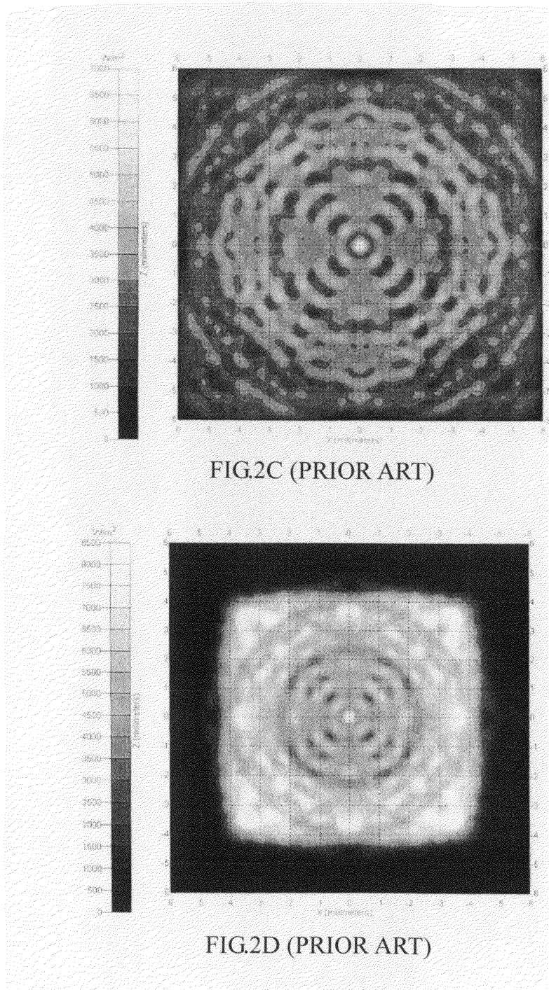

FIG. 3D is a polar diagram derived from a illumination test where a light source with a wavelength at 546.1 nm passes through the optical structure 6 of the present invention. As compared with FIG. 2C derived under identical testing conditions, it is learned that the light with the same wavelength presents an evener and more concentrated luminance when passing through the optical structure 6 of the present invention than when passing through the conventional primary lens 2.

FIG. 3E is a polar diagram derived from a illumination test where a light source with a wavelength at 1300 nm passes through the optical structure 6 of the present invention. As compared with FIG. 2D derived under identical testing conditions, it is learned that the light with the same wavelength presents an evener and more concentrated luminance when passing through the optical structure 6 of the present invention than when passing through the conventional primary lens 2. As a whole, the optical structure 6 of the present invention has a compact concentration region with improved concentration uniformity while significantly increasing luminous flux per unit area, thereby improving the photoelectric conversion efficiency of a solar cell using the optical structure 6.

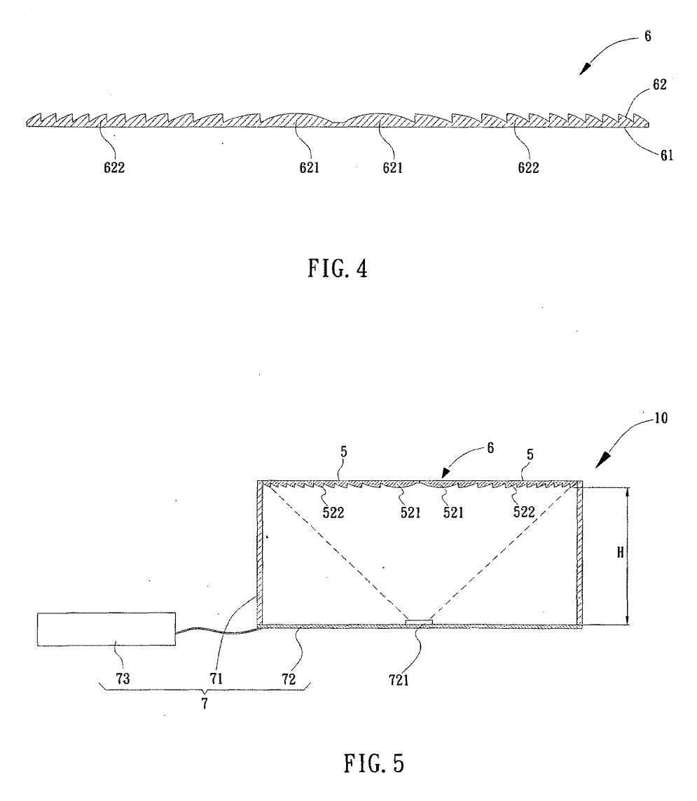

Referring to FIG. 4, the optical structure 6 of the present invention may be an integrally formed multi-focal Fresnel lens. The optical structure 6 comprises a smooth side 61 and a rough side 62. Carved at the center of the rough side 62 are a plurality of central circles 621 arranged in an annular array and a plurality of refraction portions 622 of concentric arc-shape relative to the central circles 621 and arranged in a progressive order. These refraction portions 622 are tooth-shaped in a sectional view of the optical structure 6 as shown in FIG. 4. The central circles 621 and refraction portions 622 are configured under consideration of light interference and light diffraction and according to required relative sensitivity and reception angle so that light passing therethrough is cast onto a photoelectric conversion module 7 (as shown in FIG. 5), and in consequence multiple focal points positioned differently are provided on the photoelectric conversion module 7.

The optical structure 6 is a square transparent plate with the smooth side 61 serving to receive sunlight and the rough side 62 serving to concentrate light rays passing therethrough. Of course, it is feasible that the rough side 62 serves to receive and concentrate sunlight for the smooth side 61 to further cast out the concentrated light rays. Alternatively, the optical structure 6 may be the one shown in FIG. 3A where plural identical said optical operational regions 5 are arranged in an annular array relative to a center composed of the central circles 521 on their tips, thereby forming an optical structure 6 shaped as a complete square.

Referring to FIG. 5, a solar cell 10 using the optical structure 6 of the present invention comprises at least one said optical structure 6 and the photoelectric conversion module 7. The photoelectric conversion module 7 further comprises a frame 71, a substrate 72, and a cell 73. The optical structure 6 is mounted atop the frame 71. The substrate 72 includes a circuit and is provided below the frame 71 to electrically connect with the cell 73. Beside, a semiconductor chip 721 is mounted on the substrate 72 to face the optical structure 6.

The optical structure 6 may comprise four or more said optical operational regions 5 arranged in an annular array relative to a center composed of the central circles 521 on their tips. Then the optical structure 6 is mounted atop the frame 71 of the photoelectric conversion module 7 and facing the substrate 72 with a predetermined distance H therebetween, wherein the predetermined distance H determines the focal range where the optical structure 6 casts light on the semiconductor chip 721.

When light rays enter the optical structure 6, a focal point generated by the central circles 521 and the refraction portions 522 concentric to the central circles 521 of the optical operational regions 5 is cast on to the substrate 72 so that the light rays are collected on the semiconductor chip 721 of the substrate 72 for photoelectric conversion. Afterward, the resultant electric power is stored in the cell 73 connected with the substrate 72 for being supplied to other powered devices. In the solar cell 10 using the optical structure 6 of the present invention, the semiconductor chip 721 may be a III-V semiconductor chip and the cell 73 may be one of a rechargeable lithium cell and a Ni-MH cell.

In the solar cell 10 using the optical structure 6 of the present invention, the solar cell 10 composed of the semiconductor chip 721, namely the III-V semiconductor chip (GaAs, InP, InGaP), has excellent photoelectric conversion efficiency, about 26%˜28%. When made into a multijunctiontandem cell (InGaP/GaAs//InGaAs), the photoelectric conversion efficiency can be increased to about 33.3%. Therefore, the solar cell 10 according to the present invention benefits by the reliability and stability contributed by the III-V semiconductor chip 721, thus having less tendency to aging and deterioration even working outdoor and being less sensitive to temperature variation.

The characteristic of photovoltaic concentrator has close relationship with the light concentrating factor (C) and resistance (Rs), which can be represented by the following mathematic formulas:

Current: I_{L}=CI_{L,1};

Voltage: V_{OC,C}=V_{OC,1}+(nkT/e)InC;

Power: P=CP₁+CI_{L,1}ΔV_{OC,C}−C²I_{L,1}²Rs;

Wherein, I_{L,1} is the current before the light is concentrated; V_{OC,1} is the voltage before the light is concentrated; k is the Boltzmann constant value; T is the absolute temperature.

In the other hand, by improving the uniformity of the light focused on the semiconductor chip 721, the dark current can also be reduced, the conversion efficiency can be increased, and the operating temperature of the photoelectric conversion module 7 can also be improved. The conversion efficiency of the semiconductor chip 721 of photoelectric conversion module 7 and the temperature have the following mathematic relationship:

Short-Circuit Current: the relationship between I_{SC} and temperature is:

$${I}_{SC} = {I}_{L} - {AT}^{r} [ exp ( \frac{qV - Eg}{nkT} ) ] ;$$

Wherein, T is the temperature; Eg is the energy gap of semiconductor.

Open-Circuit Voltage: the relationship between V_{OC}□I_{SC} is:

$${V}_{OC} \approx ( \frac{nkT}{e} ) ln ( \frac{{J}_{SC}}{{J}_{o}} ) .$$

Taking the solar cell 10 composed of the III-V semiconductor chip 721 as example, the photoelectric conversion efficiency thereof decreases by about 0.067% when the temperature increases by about 1° C. Thus, the multi-focal optical structure 6 also facilitates maintaining the optimal temperature for the semiconductor chip 721 by effectively lowering the peak temperature of the semiconductor chip 721 during light concentration.

In the present embodiment, the optical structure 6 may have four optical operational regions 5 as shown in FIG. 3B so as to generate four different focal points at the same time when passed by light rays and evenly distribute the four focal points over the semiconductor chip 721 (III-V semiconductor chip), thereby maintaining the semiconductor chip 721 at a relatively low temperature and thus ensuring the photoelectric conversion efficiency. In other words, the photoelectric conversion efficiency of the semiconductor chip 721 is ensured from being adversely affected by the excessive temperature happening in a single-focal optical structure.

Similarly, with quantitative increase of the optical operational regions 5 of the optical structure 6, the focal points generated by the optical operational regions 5 on the semiconductor chip 721 increase in a proportional manner while being evenly distributed over the semiconductor chip 721. Of course, a plurality of said optical structures 6 may be provided on the frame 71 of the photoelectric conversion module 7 to face and correspond to a plurality of said semiconductor chips 721 on the substrate 72 so as to further enhance the photoelectric conversion efficiency of the solar cell 10, thus achieving prompt charging the cell 73.

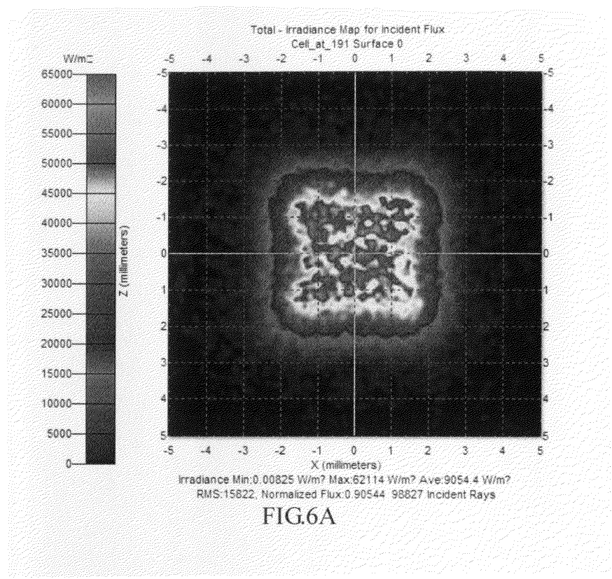

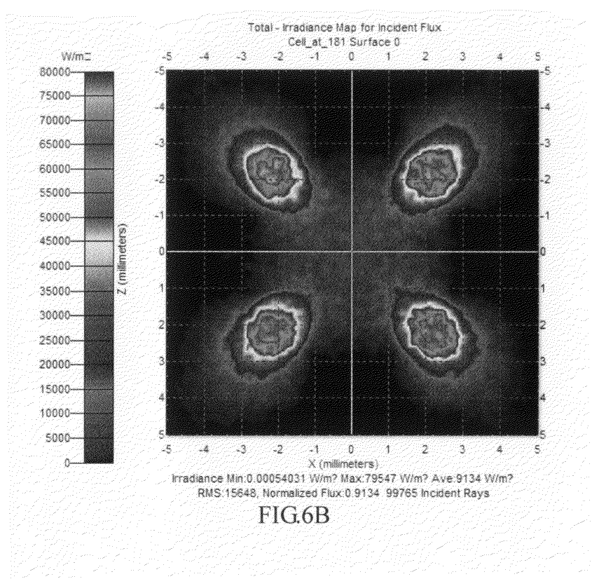

Reading FIGS. 6A and 6B with reference to FIG. 5, distribution of energy of light is measured and plotted against different distances between the disclosed optical structure 6 and the semiconductor chip 721.

As shown in FIG. 6A, when the distance H between the optical structure 6 of the solar cell 10 and the semiconductor chip 721 is relatively small, the four focal points draw light rays pass therethrough close to the center of the semiconductor chip 721. At this time, since the four focal points are partially overlapped due to the relatively small distance, the light rays are collected on the semiconductor chip 721 with enhanced uniformity and concentration while thermal energy generated by the concentrated light rays is evenly distributed over the semiconductor chip 721, but not rivet on the center of the semiconductor chip 721.

As can be seen in FIG. 6B, when the distance H between the optical structure 6 of the solar cell 10 and the semiconductor chip 721 is relatively large, the four focal points evenly distribute light rays passing therethrough to four corners of the semiconductor chip 721. At this time, owing to the increased distance, the focal range is enlarged and the multiple focal points evenly distribute thermal energy generated by the concentrated light rays over the semiconductor chip 721, thereby maintaining the semiconductor chip 721 relatively cool and ensuring the photoelectric conversion efficiency.

However, it is to be noted that the distance H between the optical structure 6 and the semiconductor chip 721 is associated with the area of the optical structure 6 that receives illumination. In other words, the larger the area of the optical structure 6 receiving light is, the longer the focal length between the optical structure 6 and the semiconductor chip 721 is, rendering the larger distance between the optical structure 6 and the semiconductor chip 721.

On the contrary, the smaller the area of the optical structure 6 receiving illumination is, the shorter the focal length between the optical structure 6 and the semiconductor chip 721 is, rendering the smaller distance between the optical structure 6 and the semiconductor chip 721. Similarly, when the optical structure 6 with a fixed area of illumination works with photoelectric conversion modules 7 in different sizes, variable focal lengths would be achievable, so as to provide the optimal focal efficiency at the semiconductor chip 721 on the substrate 72.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An optical structure, comprising a plurality of identical optical operational regions, wherein the optical operational regions based at an identical location are linked up in an annular array, the identical optical operational regions being formed by dividing a semi-finished optical structure upon divisional benchmarks that are determined by classifying wavelengths of light rays entering the semi-finished optical structure.

2. The optical structure of claim 1, wherein each of the optical operational regions comprises a central circle, and a plurality of refraction portions of concentric arc-shape relative to the central circle are arranged in a progressive order, the optical operational regions being arranged in the annular array relative to a center composed of the central circles on tips of the optical operational regions, thereby generating multiple focal points.

3. The optical structure of claim 2, wherein the refraction portions are tooth-shaped in a sectional view and are arranged in a pattern of concentric arcs relative to the central circle of the optical operational region.

4. An optical structure, comprising a rough side whereon a plurality of central circles arranged in an annular array and a plurality of refraction portions of concentric arc-shape provided and arranged in a progressive order are centrally carved, wherein each of the central circles and the refraction portions concentric to the central circle compose an optical operational region, so that the optical operational regions cast light rays onto a photoelectric conversion module and in turn generate multiple focal points.

5. The optical structure of claim 4, wherein the refraction portions are tooth-shaped in a sectional view and are arranged in a pattern of concentric arcs relative to the central circle of the optical operational region.

6. The optical structure of claim 4, wherein the photoelectric conversion module further comprises:
a frame mounted thereon with the optical structure;
a substrate including a circuit, provided below the frame, and mounted thereon with a semiconductor chip facing and corresponding in position to the optical structure; and
a cell electrically connected with the substrate;
wherein the optical structure concentrates the light rays on the semiconductor chip and converts energy of the light rays into electric power and then saves the electric power in the cell connected with the substrate for being later supplied to other powered devices.

7. The optical structure of claim 6, wherein the semiconductor chip is a □-V semiconductor chip.

8. The optical structure of claim 6, wherein the cell is one of a rechargeable lithium cell and a Ni-MH cell.

9. A solar cell using an optical structure, the solar cell comprising:
at least one said optical structure comprising a rough side whereon a plurality of central circles arranged in an annular array and a plurality of refraction portions concentric to the central circles and arranged in a progressive order are centrally carved; and
a photoelectric conversion module facing and corresponding in position to the optical structure and converting energy of light rays concentrated by the optical structure into electric power;
wherein each of the central circles and the refraction portions concentric to the central circle define an optical operational region, so that the optical operational regions cast the light rays onto a photoelectric conversion module and in turn generate multiple focal points.

10. The solar cell of claim 9, wherein the photoelectric conversion module further comprises:
a frame mounted thereon with the optical structure;
a substrate including a circuit, provided below the frame, and mounted thereon with a semiconductor chip facing and corresponding in position to the optical structure; and
a cell electrically connected with the substrate;
wherein the optical structure concentrates the light rays on the semiconductor chip and converts energy of the light rays into electric power and then saves the electric power in the cell connected with the substrate for being later supplied to other powered devices.

11. The solar cell of claim 9, wherein the refraction portions are tooth-shaped in a sectional view and are arranged in a pattern of concentric arcs relative to the central circle of the optical operational region.

12. The solar cell of claim 10, wherein the semiconductor chip is a □-V semiconductor chip.

13. The solar cell of claim 10, wherein the cell is one of a rechargeable lithium cell and a Ni-MH cell.
